(19) United States
(12) Patent Application Publication
(10) Pub. No.: US 2023/0217707 A1
(43) Pub. Date: Jul. 6, 2023

(54) DISPLAY DEVICE

(71) Applicant: LG Display Co., Ltd., Seoul (KR)

(72) Inventors: Sujin HAM, Seoul (KR); Aesun KIM, Seoul (KR)

(21) Appl. No.: 17/896,912

(22) Filed: Aug. 26, 2022

(30) Foreign Application Priority Data
Dec. 30, 2021 (KR) 10-2021-0192485

(51) Int. Cl. H01L 27/32

(52) U.S. Cl. CPC H01L 27/3262; H01L 27/3276; H01L 27/3265

(57) ABSTRACT

A display device according to an example embodiment of the present disclosure includes a stretchable lower substrate; a pattern layer disposed on the lower substrate and including a plurality of plate patterns and a plurality of line patterns; a plurality of pixels disposed on each of the plurality of plate patterns; and a plurality of connection lines disposed on each of the plurality of line patterns to connect the plurality of pixels, wherein each of the plurality of pixels includes a plurality of insulating layers, wherein at least one of the plurality of insulating layers includes at least one extension pattern extending to the plurality of line patterns.

### CROSS-REFERENCE TO RELATED APPLICATIONS

This application claims the benefit of and priority to Korean Patent Application No. 10-2021-0192485 filed on Dec. 30, 2021 in the Republic of Korea, the entire of which are hereby expressly incorporated by reference into the present application.

### BACKGROUND

### Technical Field

The present disclosure relates to a display device, and more particularly, to a stretchable display device.

### Description of the Related Art

Display devices used for a computer monitor, a TV, a mobile phone, and the like include an organic light emitting display (OLED) that emits light by itself, a liquid-crystal display (LCD) that requires a separate light source, and the like.

Such display devices are being applied to more and more various fields including not only a computer monitor and a TV, but personal mobile devices, and thus, display devices having a reduced volume and weight while having a wide active area are being studied.

Recently, a display device that is manufactured to be stretchable in a specific direction and changeable into various shapes by forming a display unit, lines, and the like on a flexible substrate such as plastic that is a flexible material has received considerable attention as a next-generation display device.

### BRIEF SUMMARY

An aspect of the present disclosure is to provide a display device capable of securing stretching reliability.

Another aspect of the present disclosure is to provide a display device capable of securing a pixel design area.

Technical benefits of the present disclosure are not limited to the above-mentioned benefits, and other benefits, which are not mentioned above, can be clearly understood by those skilled in the art from the following descriptions.

A display device according to an example embodiment of the present disclosure includes a stretchable lower substrate; a pattern layer disposed on the lower substrate and including a plurality of plate patterns and a plurality of line patterns; a plurality of pixels disposed on each of the plurality of plate patterns; and a plurality of connection lines disposed on each of the plurality of line patterns to connect the plurality of pixels, wherein each of the plurality of pixels includes a plurality of insulating layers, wherein at least one of the plurality of insulating layers includes at least one extension pattern extending to the plurality of line patterns.

A display device according to another example embodiment of the present disclosure includes a stretchable substrate; a plurality of island patterns spaced apart from each other on the stretchable substrate; a plurality of pixels disposed on each of the plurality of island patterns; and a plurality of connection lines connecting the plurality of pixels, wherein each of the plurality of pixels includes a plurality of insulating layers, wherein at least one of the plurality of insulating layers overlaps the plurality of connection lines and includes at least one extension pattern extending to outsides of the plurality of island patterns.

Other matters of the example embodiments are included in the detailed description and the drawings.

According to the present disclosure, over-etching at a boundary between a plate pattern and a line pattern is prevented by disposing an insulating layer at the boundary between the plate pattern and the line pattern, so that stability of a display device can be improved.

According to the present disclosure, by fixing a connection line through an anchor hole, it is possible to prevent the connection line from being peeled off.

According to the present disclosure, a pixel design area can be effectively secured by disposing a contact hole in a line pattern.

The effects according to the present disclosure are not limited to the contents exemplified above, and more various effects are included in the present specification.

### BRIEF DESCRIPTION OF THE SEVERAL VIEWS OF THE DRAWINGS

FIG. 1 is a plan view of a display device according to an example embodiment of the present disclosure.

FIG. 2 is an enlarged plan view of an active area of the display device according to an example embodiment of the present disclosure.

FIG. 3 is a cross-sectional view taken along cutting line III-III′ shown in FIG. 2.

FIGS. 4A and 4B are cross-sectional views taken along cutting line IV-IV′ shown in FIG. 2.

FIG. 5 is a cross-sectional view taken along cutting line V-V′ shown in FIG. 2.

FIG. 6 is a circuit diagram of a sub-pixel of the display device according to an example embodiment of the present disclosure.

FIGS. 7A to 7E are cross-sectional views illustrating extension patterns of the display device according to example embodiments of the present disclosure.

FIG. 8 is an enlarged plan view of an active area of a display device according to another example embodiment of the present disclosure.

FIG. 9 is a cross-sectional view taken along cutting line IX-IX′ shown in FIG. 8.

FIG. 10 is an enlarged plan view of an active area of a display device according to still another example embodiment of the present disclosure.

FIGS. 11A and 11B are cross-sectional views taken along cutting line XI-XI′ shown in FIG. 10.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

A display device according to an example embodiment of the present disclosure is a display device capable of displaying an image even if it is bent or stretched, and may also be referred to as a stretchable display device or a flexible display device. The display device may have higher flexibility and stretchability than conventional, typical display devices. Accordingly, a user can bend or stretch the display device, and a shape of the display device can be freely changed according to the user's manipulation. For example, when the user grabs and pulls an end of the display device, the display device may be stretched in a pulling direction by the user. If the user places the display device on an uneven outer surface, the display device can be disposed to be bent according to a shape of the outer surface. When force applied by the user is removed, the display device can return to an original shape thereof. A display device according to an example embodiment of the present disclosure is a display device capable of displaying an image even if it is bent or stretched, and may also be referred to as a display device, a stretchable display device or a flexible display device. The display device may have higher flexibility and stretchability than conventional, typical display devices. Accordingly, a user can bend or stretch the display device, and a shape of the display device can be freely changed according to the user's manipulation. For example, when the user grabs and pulls an end of the display device, the display device may be stretched in a pulling direction by the user. If the user places the display device on an uneven outer surface, the display device can be disposed to be bent according to a shape of the outer surface. When force applied by the user is removed, the display device can return to an original shape thereof.

### Stretchable Substrate and Pattern Layer

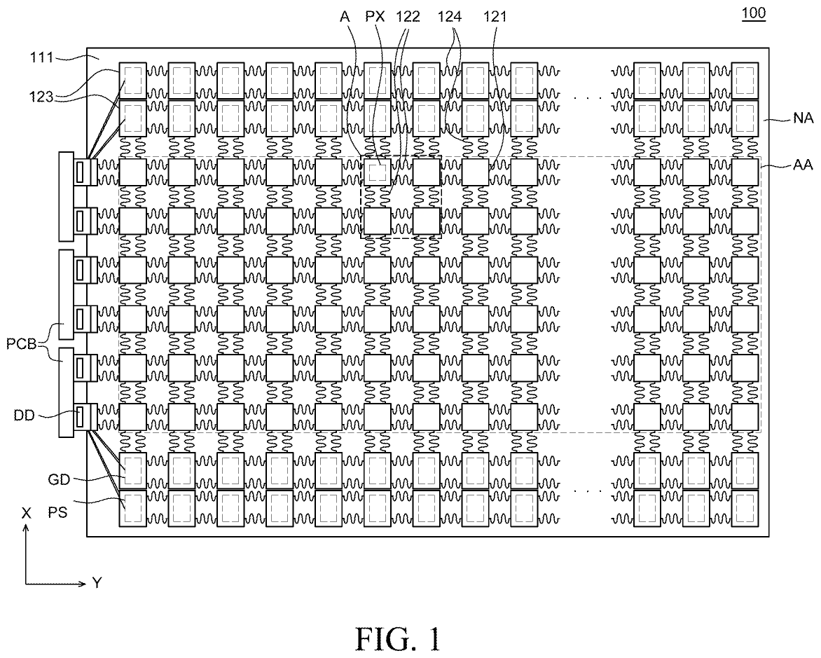

FIG. 1 is a plan view of a display device according to an example embodiment of the present disclosure.

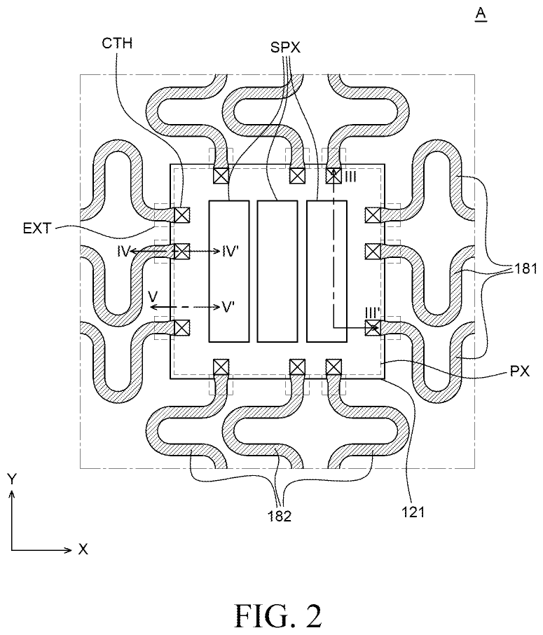

FIG. 2 is an enlarged plan view of an active area of the display device according to an example embodiment of the present disclosure.

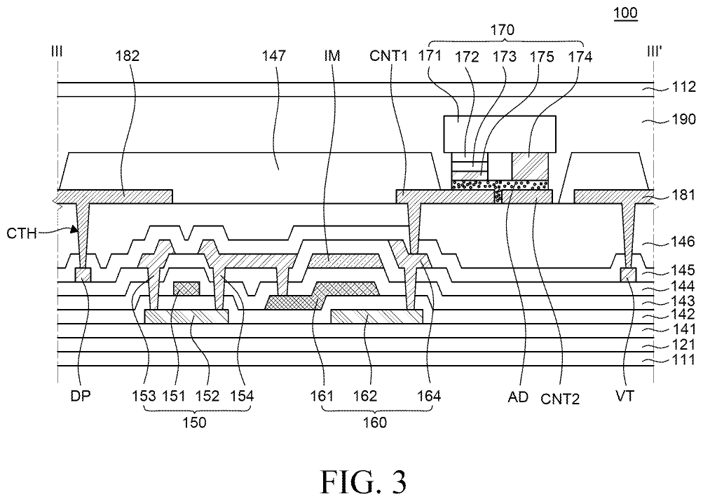

FIG. 3 is a cross-sectional view taken along cutting line III-III′ shown in FIG. 2.

Specifically, FIG. 2 is an enlarged plan view of area A shown in FIG. 1.

Referring to FIG. 1, a display device 100 according to an example embodiment of the present disclosure may include a lower substrate 111, a pattern layer 120, a plurality of pixels PX, gate drivers GD, data drivers DD, and power supplies PS. And, referring to FIG. 1, the display device 100 according to an example embodiment of the present disclosure may further include a filling layer 190 and an upper substrate 112.

The lower substrate 111 is a substrate for supporting and protecting various components of the display device 100. In addition, the upper substrate 112 is a substrate for covering and protecting various components of the display device 100. That is, the lower substrate 111 is a substrate that supports the pattern layer 120 on which the pixels PX, the gate drivers GD, and the power supplies PS are formed. In addition, the upper substrate 112 is a substrate that covers the pixels PX, the gate drivers GD, and the power supplies PS.

Each of the lower substrate 111 and the upper substrate 112 is a ductile substrate and may be formed of an insulating material that can be bent or stretched. For example, each of the lower substrate 111 and the upper substrate 112 may be formed of silicone rubber such as polydimethylsiloxane (PDMS) or elastomers such as polyurethane (PU) and polytetrafluoroethylene (PTFE), and thus, may have flexible properties. In addition, materials of the lower substrate 111 and the upper substrate 112 may be the same, but are not limited thereto and may be variously modified.

Each of the lower substrate 111 and the upper substrate 112 is a ductile substrate and may be reversibly expandable and contractible. Accordingly, the lower substrate 111 may be referred to as a lower stretchable substrate, a lower flexible substrate, a lower extendable substrate, a lower ductile substrate, a first stretchable substrate, a first flexible substrate, a first extendable substrate, or a first ductile substrate, and the upper substrate 112 may be referred to as an upper stretchable substrate, an upper flexible substrate, an upper extendable substrate, an upper ductile substrate, a second stretchable substrate, a second flexible substrate, a second extendable substrate, or a second ductile substrate. Further, moduli of elasticity of the lower substrate 111 and the upper substrate 112 may be several MPa to several hundreds of MPa. Further, a ductile breaking rate of the lower substrate 111 and the upper substrate 112 may be 100% or higher. Here, the ductile breaking rate refers to a stretching rate at a time at which an object that is stretched is broken or cracked. A thickness of the lower substrate may be 10 μm to 1 mm, but is not limited thereto. Here, the ductile breaking rate refers to an extension distance when an object to be stretched is broken or cracked. That is, the ductile breaking rate is defined as a percentage ratio of a length of an original object and a length of the stretched object when an object has been stretched sufficiently that it is considered broken. For example, if a length of an object (e.g., substrate) is 100 cm when the object is not stretched and then, it reaches a length of 110 cm when the object has been stretched enough that it becomes broken or cracked at this length, then it was been stretched to 110% of its original length. In this case, the ductile breaking rate of the object is 110%. The number could thus also be called a ductile breaking ratio since it is a ratio of the stretched length as the numerator compared to the original upstretched length as the denominator at the time the break occurs.

The lower substrate 111 may have an active area AA and a non-active area NA surrounding the active area AA. However, the active area AA and the non-active area NA are not limited to the lower substrate 111 and may be referred throughout the display device.

The active area AA is an area in which an image is displayed on the display device 100. The plurality of pixels PX are disposed in the active area AA. In addition, each of the pixels PX may include a display element and various driving elements for driving the display element. The various driving elements may mean at least one thin film transistor TFT and a capacitor, but are not limited thereto. In addition, each of the plurality of pixels PX may be connected to various lines. For example, each of the plurality of pixels PX may be connected to various lines such as gate lines, data lines, high potential voltage lines, low potential voltage lines, reference voltage lines and initialization voltage lines.

The non-active area NA is an area in which an image is not displayed. The non-active area NA may be an area adjacent to the active area AA. And, the non-active area NA may be an area that is adjacent to and surrounds the active area AA. However, the present disclosure is not limited thereto, and the non-active area NA corresponds to an area of the lower substrate 111 excluding the active area AA and may be changed and separated into various shapes. Components for driving the plurality of pixels PX disposed in the active area AA are disposed in the non-active area NA. The gate drivers GD and power supplies PS may be disposed in the non-active area NA. In addition, a plurality of pads that are connected to the gate drivers GD and the data drivers DD may be disposed in the non-active area NA, and each of the pads may be connected to each of the plurality of pixels PX in the active area AA.

On the lower substrate 111, the pattern layer 120 including a plurality of first plate patterns 121 and a plurality of first line patterns 122 that are disposed in the active area AA and a plurality of second plate patterns 123 and a plurality of second line patterns 124 that are disposed in the non-active area NA is disposed.

The plurality of first plate patterns 121 may be disposed in the active area AA of the lower substrate 111. The plurality of pixels PX may be formed on the plurality of first plate patterns 121. In addition, the plurality of second plate patterns 123 may be disposed in the non-active area NA of the lower substrate 111. In addition, the gate drivers GD and the power supplies PS may be formed on the plurality of second plate patterns 123.

The plurality of first plate patterns 121 and the plurality of second plate patterns 123 as described above may be disposed in the form of islands that are spaced apart from each other. Each of the plurality of first plate patterns 121 and the plurality of second plate patterns 123 may be individually separated. Accordingly, the plurality of first plate patterns 121 and the plurality of second plate patterns 123 may be referred to as first island patterns and second island patterns, or first individual patterns and second individual patterns.

Specifically, the gate drivers GD may be mounted on the plurality of second plate patterns 123. The gate driver GD may be formed on the second plate pattern 123 in a gate in panel (GIP) method when various components on the first plate pattern 121 are manufactured. Accordingly, various circuit components constituting the gate drivers GD such as various transistors, capacitors, and lines may be disposed on the plurality of second plate patterns 123. However, the present disclosure is not limited thereto, and the gate driver GD may be mounted in a chip on film (COF) method.

In addition, the power supplies PS may be mounted on the plurality of second plate patterns 123. The power supply PS may be formed on the second plate pattern 123 with a plurality of power blocks that are patterned when various components on the first plate pattern 121 are manufactured. Accordingly, the power blocks disposed on different layers may be disposed on the second plate pattern 123. That is, a lower power block and an upper power block may be sequentially disposed on the second plate pattern 123. In addition, a low potential voltage may be applied to the lower power block, and a high potential voltage may be applied to the upper power block. Accordingly, the low potential voltage may be supplied to the plurality of pixels PX through the lower power block. In addition, the high potential voltage may be supplied to the plurality of pixels PX through the upper power block.

Referring to FIG. 1, sizes of the plurality of second plate patterns 123 may be greater than sizes of the plurality of first plate patterns 121. Specifically, the size of each of the plurality of second plate patterns 123 may be greater than the size of each of the plurality of first plate patterns 121. As described above, the gate driver GD may be disposed on each of the plurality of second plate patterns 123, and one stage of the gate driver GD may be disposed on each of the plurality of second plate patterns 123. Accordingly, since an area that is occupied by various circuit components constituting one stage of the gate driver GD is relatively greater than an area occupied by the pixels PX, the size of each of the plurality of second plate patterns 123 may be greater than the size of each of the first plate patterns 121.

In FIG. 1, the plurality of second plate patterns 123 are illustrated as being disposed on both sides in a first direction X in the non-active area NA, but the present disclosure is not limited thereto, and the plurality of second plate patterns 123 may be disposed in any area of the non-active area NA. In addition, although the plurality of first plate patterns 121 and the plurality of second plate patterns 123 are shown in a quadrangular shape, the present disclosure is not limited thereto, and the plurality of first plate patterns 121 and the plurality of second plate patterns 123 are changeable in various forms.

Referring to FIG. 1, the pattern layer 120 may further include the plurality of first line patterns 122 disposed in the active area AA and the plurality of second line patterns 124 disposed in the non-active area NA.

The plurality of first line patterns 122 are patterns that are disposed in the active area AA and connect the first plate patterns 121 adjacent to each other, and may be referred to as first connection patterns. That is, the plurality of first line patterns 122 are disposed between the plurality of first plate patterns 121.

The plurality of second line patterns 124 may be patterns that are disposed in the non-active area NA and connect the first plate patterns 121 and the second plate patterns 123 adjacent to each other or the plurality of second plate patterns 123 adjacent to each other. Accordingly, the plurality of second line patterns 124 may be referred to as second connection patterns. And, the plurality of second line patterns 124 may be disposed between the first plate patterns 121 and the second plate patterns 123 that are adjacent to each other, and disposed between the plurality of second plate patterns 123 that are adjacent to each other. Referring to FIG. 1, the plurality of first line patterns 122 and the plurality of second line patterns 124 have a wavy shape. For example, the plurality of first line patterns 122 and the plurality of second line patterns 124 may have a sine wave shape. However, the shapes of the plurality of first line patterns 122 and the plurality of second line patterns 124 are not limited thereto. For example, the plurality of first line patterns 122 and the plurality of second line patterns 124 may extend in a zigzag manner. Alternatively, shapes of the plurality of first line patterns 122 and the plurality of the second line patterns 124 may have various shapes, such as shapes in which a plurality of rhombus-shaped substrates are extended by being connected at vertices thereof. In addition, the numbers and shapes of the plurality of first line patterns 122 and the second line patterns 124 illustrated in FIG. 1 are examples, and the numbers and shapes of the plurality of first line patterns 122 and the second line patterns 124 may be variously changed according to design.

In addition, the plurality of first plate patterns 121, the plurality of first line patterns 122, the plurality of second plate patterns 123, and the plurality of second line patterns 124 are rigid patterns. That is, the plurality of first plate patterns 121, the plurality of first line patterns 122, the plurality of second plate patterns 123, and the plurality of second line patterns 124 may be rigid compared to the lower substrate 111 and the upper substrate 112. Accordingly, moduli of elasticity of the plurality of first plate patterns 121, the plurality of first line patterns 122, the plurality of second plate patterns 123, and the plurality of second line patterns 124 may be higher than a modulus of elasticity of the lower substrate 111. The modulus of elasticity is a parameter representing a rate of deformation against a stress applied to the substrate. When the modulus of elasticity is relatively high, hardness may be relatively high. Accordingly, the plurality of first plate patterns 121, the plurality of first line patterns 122, the plurality of second plate patterns 123, and the plurality of second line patterns 124 may be referred to as a plurality of first rigid patterns, a plurality of second rigid patterns, a plurality of third rigid patterns, and a plurality of fourth rigid patterns, respectively. The moduli of elasticity of the plurality of first plate patterns 121, the plurality of first line patterns 122, the plurality of second plate patterns 123, and the plurality of second line patterns 124 may be 1000 times higher than the moduli of elasticity of the lower substrate 111 and the upper substrate 112, but the present disclosure is not limited thereto.

The plurality of first plate patterns 121, the plurality of first line patterns 122, the plurality of second plate patterns 123, and the plurality of second line patterns 124 that are a plurality of rigid substrates may be formed of a plastic material having flexibility that is lower than that of the lower substrate 111 and the upper substrate 112. For example, the plurality of first plate patterns 121, the plurality of first line patterns 122, the plurality of second plate patterns 123, and the plurality of second line patterns 124 may be formed of at least one material among polyimide (PI), polyacrylate and polyacetate. In this case, the plurality of first plate patterns 121, the plurality of first line patterns 122, the plurality of second plate patterns 123, and the plurality of second line patterns 124 may be formed of the same material, but they are not limited thereto and may be formed of different materials. When the plurality of first plate patterns 121, the plurality of first line patterns 122, the plurality of second plate patterns 123, and the plurality of second line patterns 124 are formed of the same material, they may be integrally formed.

In some embodiments, the lower substrate 111 may be defined as including a plurality of first lower patterns and a second lower pattern. The plurality of first lower patterns may be areas of the lower substrate 111 that overlap the plurality of first plate patterns 121 and the plurality of second plate patterns 123, and the second lower pattern may be an area that does not overlap the plurality of first plate patterns 121 and the plurality of second plate patterns 123.

Also, the upper substrate 112 may be defined as including a plurality of first upper patterns and a second upper pattern. The plurality of first upper patterns may be areas of the upper substrate 112 that overlap the plurality of first plate patterns 121 and the plurality of second plate patterns 123. The second upper pattern may be an area that does not overlap the plurality of first plate patterns 121 and the plurality of second plate patterns 123.

In this case, moduli of elasticity of the plurality of first lower patterns and first upper patterns may be higher than moduli of elasticity of the second lower patterns and the second upper patterns. For example, the plurality of first lower patterns and the first upper patterns may be formed of the same material as the plurality of first plate patterns 121 and the plurality of second plate patterns 123, and the second lower pattern and the second upper pattern may be formed of a material having a modulus of elasticity lower than those of the plurality of first plate patterns 121 and the plurality of second plate patterns 123.

That is, the first lower pattern and the first upper pattern may be formed of polyimide (PI), polyacrylate, polyacetate, or the like, and the second lower pattern and the second upper pattern may be formed of silicon rubber such as polydimethylsiloxane (PDMS) or elastomers such as polyurethane (PU), polytetrafluoroethylene (PTFE) and the like.

### Non-Active Area Driving Element

The gate drivers GD are components which supply a gate voltage to the plurality of pixels PX disposed in the active area AA. The gate drivers GD include a plurality of stages formed on the plurality of second plate patterns 123 and respective stages of the gate drivers GD may be electrically connected to each other through a plurality of gate connection lines. Accordingly, a gate voltage output from any one of stages may be transmitted to another stage. Further, the respective stages may sequentially supply the gate voltage to the plurality of pixels PX connected to the respective stages.

The power supplies PS may be connected to the gate drivers GD and supply a gate driving voltage and a gate clock voltage. Further, the power supplies PS may be connected to the plurality of pixels PX and supply a pixel driving voltage to each of the plurality of pixels PX. The power supplies PS may also be formed on the plurality of second plate patterns 123. That is, the power supplies PS may be formed on the plurality of second plate patterns 123 to be adjacent to the gate drivers GD. Further, each of the power supplies PS formed on the plurality of second plate patterns 123 may be electrically connected to the gate driver GD and the plurality of pixels PX. That is, the plurality of power supplies PS formed on the plurality of second plate patterns 123 may be connected by a gate power supply connection line and a pixel power supply connection line. Therefore, each of the plurality of power supplies PS may supply a gate driving voltage, a gate clock voltage, and a pixel driving voltage.

The printed circuit board PCB is a component which transmits signals and voltages for driving the display element from a control unit to the display element. Therefore, the printed circuit board PCB may also be referred to as a driving substrate. A control unit such as an IC chip or a circuit may be mounted on the printed circuit board PCB. Further, a memory, a processor or the like may be mounted on the printed circuit board PCB. Further, the printed circuit board PCB provided in the display device 100 may include a stretchable area and a non-stretchable area to secure stretchability. Also, on the non-stretchable area, an IC chip, a circuit, a memory, a processor and the like may be mounted, and in the stretchable area, lines electrically connected to the IC chip, the circuit, the memory and the processor may be disposed.

The data driver DD is a component which supplies a data voltage to the plurality of pixels PX disposed in the active area AA. The data driver DD may be configured in a form of an IC chip and thus, may also be referred to as a data integrated circuit D-IC. Further, the data driver DD may be mounted on the non-stretchable area of the printed circuit board PCB. That is, the data driver DD may be mounted on the printed circuit board PCB in a form of a chip on board (COB). Although in FIG. 1, it is illustrated that the data driver DD is mounted in a chip on board (COB) manner, the present disclosure is not limited thereto and the data driver DD may be mounted in a chip on film (COF), a chip on glass (COG), a tape carrier package (TCP) manner, or the like.

Also, although it is illustrated in FIG. 1 that one data driver DD is disposed to correspond to a line of the first plate patterns 121 disposed in the active area AA, the present disclosure is not limited thereto. That is, one data driver DD may be disposed to correspond to a plurality of columns of the first plate patterns 121.

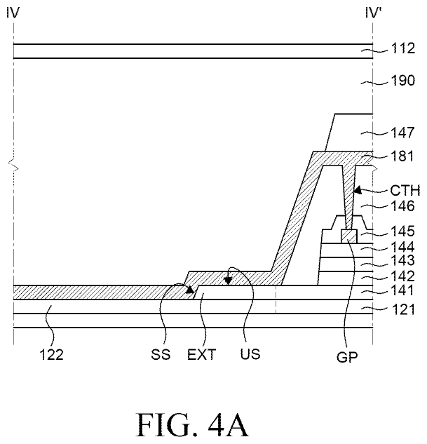

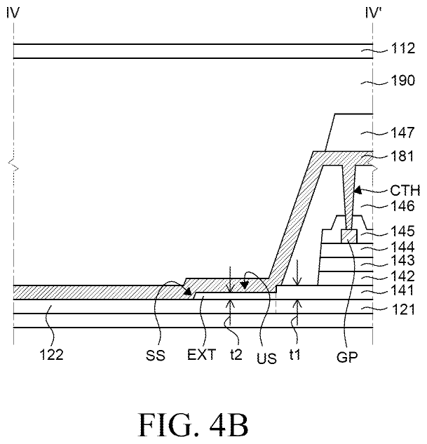

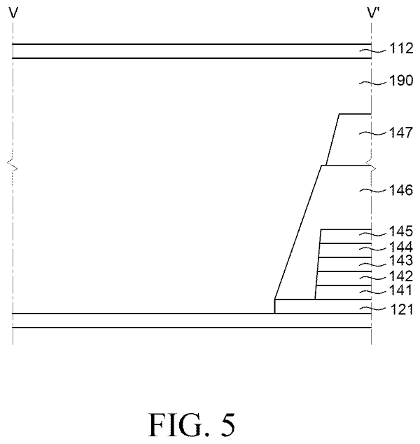

Hereinafter, FIGS. 4A and 4B and FIG. 5 are referred together for a more detailed description of the active area AA of the display device 100 according to an example embodiment of the present disclosure.

### Planar and Cross-Sectional Structures of Active Area

FIGS. 4A and 4B are cross-sectional views taken along cutting line IV-IV′ shown in FIG. 2.

FIG. 5 is a cross-sectional view taken along cutting line V-V′ shown in FIG. 2.

Specifically, FIG. 4A illustrates a case in which a thickness of an extension pattern EXT is equal to a thickness of a buffer layer 141, and FIG. 4B illustrates a case in which the thickness of the extension pattern EXT is smaller than the thickness of the buffer layer 141.

FIGS. 1 to 3 are referred together for convenience of explanation.

Referring to FIG. 1 and FIG. 2, the plurality of first plate patterns 121 are disposed on the lower substrate 111 in the active area AA. The plurality of first plate patterns 121 are disposed to be spaced apart from each other on the lower substrate 111. For example, the plurality of first plate patterns 121 may be disposed in a matrix form on the lower substrate 111 as shown in FIG. 1, but are not limited thereto.

Referring to FIG. 2 and FIG. 3, pixels PX including a plurality of sub-pixels SPX are disposed on the first plate pattern 121. Also, each of the sub-pixels SPX may include an LED 170, which is a display element and a driving transistor 160 and a switching transistor 150 for driving the

LED 170. However, the display element in the sub-pixel SPX is not limited to the LED and may be an organic light emitting diode. Further, the plurality of sub-pixels SPX may include a red sub-pixel, a green sub-pixel, and a blue sub-pixel, but are not limited thereto. Colors of the plurality of sub-pixels SPX may be variously changed as needed.

The plurality of sub-pixels SPX may be connected to a plurality of connection lines 181 and 182. That is, the plurality of sub-pixels SPX may be electrically connected to the first connection lines 181 extended in the first direction X. Also, the plurality of sub-pixels SPX may be electrically connected to the second connection lines 182 extended in a second direction Y.

Hereinafter, a cross-sectional structure of the active area AA will be described in detail with reference to FIG. 3.

Referring to FIG. 3, a plurality of inorganic insulating layers are disposed on the plurality of first plate patterns 121. For example, the plurality of inorganic insulating layers may include the buffer layer 141, a gate insulating layer 142, a first interlayer insulating layer 143, a second interlayer insulating layer 144, and a passivation layer 145. However, the present disclosure is not limited thereto. Various inorganic insulating layers may be further disposed on the plurality of first plate patterns 121. One or more of the buffer layer 141, the gate insulating layer 142, the first interlayer insulating layer 143, the second interlayer insulating layer 144, and the passivation layer 145 which are inorganic insulating layers may be omitted.

Specifically, the buffer layer 141 is disposed on the plurality of first plate patterns 121. The buffer layer 141 is formed on the plurality of first plate patterns 121 to protect various components of the display device 100 against permeation of moisture (H₂O), oxygen (O₂) or the like from the outside of the lower substrate 111 and the plurality of first plate patterns 121. The buffer layer 141 may be formed of an insulating material. For example, the buffer layer 141 may be formed as a single layer or multiple layers of silicon nitride (SiNx), silicon oxide (SiOx), silicon oxynitride (SiON), or the like. However, the buffer layer 141 may be omitted depending on a structure or characteristics of the display device 100.

In this case, the buffer layer 141 may be formed in an area where the buffer layer 141 overlaps the plurality of first plate patterns 121 and the plurality of second plate patterns 123. As described above, the buffer layer 141 may be formed of an inorganic material. Thus, the buffer layer 141 may be easily damaged, such as easily cracked, while the display device 100 is stretched. Therefore, the buffer layer 141 may not be formed in areas between the plurality of first plate patterns 121 and the plurality of second plate patterns 123. The buffer layer 141 may be patterned into shapes of the plurality of first plate patterns 121 and the plurality of second plate patterns 123 and formed on top surfaces of the plurality of first plate patterns 121 and the plurality of second plate patterns 123. Accordingly, in the display device 100 according to an example embodiment of the present disclosure, the buffer layer 141 is formed in the area where the buffer layer 141 overlaps the plurality of first plate patterns 121 and the plurality of second plate patterns 123 which are rigid substrates, so that damage to various components of the display device 100 may be prevented even when the display device 100 is deformed, such as bent or stretched.

Referring to FIG. 3, the switching transistor 150 including a gate electrode 151, an active layer 152, a source electrode 153 and a drain electrode 154, and the driving transistor 160 including a gate electrode 161, an active layer 162, a source electrode and a drain electrode 164 are formed on the buffer layer 141. That is, the buffer layer 141 may be disposed between the plurality of first plate patterns 121 and the active layers 152 and 162.

First, referring to FIG. 1, the active layer 152 of the switching transistor 150 and the active layer 162 of the driving transistor 160 are disposed on the buffer layer 141. For example, each of the active layer 152 of the switching transistor 150 and the active layer 162 of the driving transistor 160 may be formed of an oxide semiconductor. Alternatively, the active layer 152 of the switching transistor 150 and the active layer 162 of the driving transistor 160 may be formed of amorphous silicon (a-Si), polycrystalline silicon (poly-Si), an organic semiconductor or the like.

The gate insulating layer 142 is disposed on the active layer 152 of the switching transistor 150 and the active layer 162 of the driving transistor 160. The gate insulating layer 142 is configured to electrically insulate the gate electrode 151 of the switching transistor 150 from the active layer 152 of the switching transistor 150 and electrically insulate the gate electrode 161 of the driving transistor 160 from the active layer 162 of the driving transistor 160. Further, the gate insulating layer 142 may be formed of an insulating material. For example, the gate insulating layer 142 may be formed as a single layer of silicon nitride (SiNx) or silicon oxide (SiOx) or multiple layers of silicon nitride (SiNx) or silicon oxide (SiOx), but is not limited thereto.

The gate electrode 151 of the switching transistor 150 and the gate electrode 161 of the driving transistor 160 are disposed on the gate insulating layer 142. The gate electrode 151 of the switching transistor 150 and the gate electrode 161 of the driving transistor 160 are disposed to be spaced apart from each other on the gate insulating layer 142. Further, the gate electrode 151 of the switching transistor 150 overlaps the active layer 152 of the switching transistor 150, and the gate electrode 161 of the driving transistor 160 overlaps the active layer 162 of the driving transistor 160. That is, the gate insulating layer 142 is disposed between the active layers 152 and 162 and the gate electrodes 151 and 161.

Each of the gate electrode 151 of the switching transistor 150 and the gate electrode 161 of the driving transistor 160 may be formed of any one of various metal materials, for example, any one of molybdenum (Mo), aluminum (Al), chromium (Cr), gold (Au), titanium (Ti), nickel (Ni), neodymium (Nd) and copper (Cu). Alternatively, each of the gate electrode 151 of the switching transistor 150 and the gate electrode 161 of the driving transistor 160 may be formed of an alloy of two or more of them, or a plurality of layer thereof, but is not limited thereto.

The first interlayer insulating layer 143 is disposed on the gate electrode 151 of the switching transistor 150 and the gate electrode 161 of the driving transistor 160. The first interlayer insulating layer 143 is disposed between the gate electrode 161 of the driving transistor 160 and an intermediate metal layer IM and insulates the gate electrode 161 of the driving transistor 160 from the intermediate metal layer IM. The first interlayer insulating layer 143 may also be formed of an inorganic material like the buffer layer 141. For example, the first interlayer insulating layer 143 may be formed as a single layer of silicon nitride (SiNx) or silicon oxide (SiOx) or multiple layers of silicon nitride (SiNx) or silicon oxide (SiOx), but is not limited thereto.

The intermediate metal layer IM is disposed on the first interlayer insulating layer 143. Further, the intermediate metal layer IM overlaps the gate electrode 161 of the driving transistor 160. Thus, a storage capacitor is formed in an area where the intermediate metal layer IM overlaps the gate electrode 161 of the driving transistor 160. Specifically, the gate electrode 161 of the driving transistor 160, the first interlayer insulating layer 143 and the intermediate metal layer IM form the storage capacitor. However, a position of the intermediate metal layer IM is not limited thereto. The intermediate metal layer IM may overlap another electrode to form a storage capacitor in various ways.

The intermediate metal layer IM may be formed of any one of various metal materials, for example, any one of molybdenum (Mo), aluminum (Al), chromium (Cr), gold (Au), titanium (Ti), nickel (Ni), neodymium (Nd) and copper (Cu). Alternatively, the intermediate metal layer IM may be formed of an alloy of two or more of them, or a plurality of layer thereof, but is not limited thereto.

The second interlayer insulating layer 144 is disposed on the intermediate metal layer IM. The second interlayer insulating layer 144 is disposed between the gate electrode 151 of the switching transistor 150 and the source electrode 153 and the drain electrode 154 of the switching transistor 150, and insulates the gate electrode 151 of the switching transistor 150 from the source electrode 153 and the drain electrode 154 of the switching transistor 150. Also, the second interlayer insulating layer 144 is disposed between the intermediate metal layer IM and the source electrode and the drain electrode 164 of the driving transistor 160 and insulates the intermediate metal layer IM from the source electrode and the drain electrode 164 of the driving transistor 160. The second interlayer insulating layer 144 may also be formed of an inorganic material like the buffer layer 141. For example, the first interlayer insulating layer 143 may be formed as a single layer of silicon nitride (SiNx) or silicon oxide (SiOx) or multiple layers of silicon nitride (SiNx) or silicon oxide (SiOx), but is not limited thereto.

The source electrode 153 and the drain electrode 154 of the switching transistor 150 are disposed on the second interlayer insulating layer 144. Also, the source electrode and the drain electrode 164 of the driving transistor 160 are disposed on the second interlayer insulating layer 144. The source electrode 153 and the drain electrode 154 of the switching transistor 150 are disposed to be spaced apart from each other on the same layer. Further, although FIG. 1 does not illustrate the source electrode of the driving transistor 160, the source electrode of the driving transistor 160 is also disposed to be spaced apart from the drain electrode 164 of the driving transistor 160 on the same layer. In the switching transistor 150, the source electrode 153 and the drain electrode 154 may be electrically connected to the active layer 152 to be in contact with the active layer 152. Also, in the driving transistor 160, the source electrode and the drain electrode 164 may be electrically connected to the active layer 162 to be in contact with the active layer 162. Further, the drain electrode 154 of the switching transistor 150 may be electrically connected to the gate electrode 161 of the driving transistor 160 to be in contact with the gate electrode 161 of the driving transistor 160 through a contact hole.

The source electrode 153 and the drain electrodes 154 and 164 may be formed of any one of various metal materials, for example, any one of molybdenum (Mo), aluminum (Al), chromium (Cr), gold (Au), titanium (Ti), nickel (Ni), neodymium (Nd) and copper (Cu). Alternatively, the source electrode 153 and the drain electrodes 154 and 164 may be formed of an alloy of two or more of them, or a plurality of layer thereof, but are not limited thereto.

Further, in the present disclosure, the driving transistor 160 has been described as having a coplanar structure, but various types of transistors having a staggered structure or the like may also be used. Also, in the present disclosure, the transistor may be formed not only in a top gate structure but also in a bottom gate structure.

A gate pad GP and a data pad DP may be disposed on the second interlayer insulating layer 144.

Specifically, referring to FIGS. 4A and 4B, the gate pad GP serves to transfer a gate voltage to the plurality of sub-pixels SPX. The gate pad GP is connected to the first connection line 181 through a contact hole CTH formed in the first plate pattern 121. In addition, the gate voltage supplied from the first connection line 181 may be transferred from the gate pad GP to the gate electrode 151 of the switching transistor 150 through a line formed on the first plate pattern 121.

In addition, referring to FIG. 3, the data pad DP serves to transfer a data voltage to the plurality of sub-pixels SPX. The data pad DP is connected to the second connection line 182 through a contact hole CTH formed in the first plate pattern 121. In addition, the data voltage supplied from the second connection line 182 may be transferred from the data pad DP to the source electrode 153 of the switching transistor 150 through a line formed on the first plate pattern 121.

And, referring to FIG. 3, a voltage pad VT is a pad for transferring a low potential voltage to the plurality of sub-pixels SPX. The voltage pad VT is connected to the first connection line 181 through the contact hole. In addition, the low potential voltage supplied from the first connection line 181 may be transferred from the voltage pad VT to an n-electrode 174 of the LED 170 through a second contact pad CNT2 formed on the first plate pattern 121.

The gate pad GP and the data pad DP may be formed of the same material as the source electrode 153 and the drain electrodes 154 and 164, but are not limited thereto.

Referring to FIG. 1, the passivation layer 145 is formed on the switching transistor 150 and the driving transistor 160. The passivation layer 145 covers the switching transistor 150 and the driving transistor 160 to protect the switching transistor 150 and the driving transistor 160 against permeation of moisture, oxygen, and the like. The passivation layer 145 may be formed of an inorganic material and formed as a single layer or a plurality of layers, but is not limited thereto.

Also, the gate insulating layer 142, the first interlayer insulating layer 143, the second interlayer insulating layer 144 and the passivation layer 145 may be patterned and formed in an area where they overlap the plurality of first plate patterns 121. The gate insulating layer 142, the first interlayer insulating layer 143, the second interlayer insulating layer 144 and the passivation layer 145 may also be formed of an inorganic material like the buffer layer 141. Thus, the gate insulating layer 142, the first interlayer insulating layer 143, the second interlayer insulating layer 144 and the passivation layer 145 may be easily damaged, such as easily cracked, while the display device 100 is stretched. Therefore, the gate insulating layer 142, the first interlayer insulating layer 143, the second interlayer insulating layer 144 and the passivation layer 145 may not be formed in areas between the plurality of first plate patterns 121 and may be patterned into the shapes of the plurality of first plate patterns 121 and formed on top surfaces of the plurality of first plate patterns 121.

A planarization layer 146 is formed on the passivation layer 145. The planarization layer 146 serves to flatten top surfaces of the switching transistor 150 and the driving transistor 160. The planarization layer 146 may be formed as a single layer or a plurality of layers and may be formed of an organic material. Thus, the planarization layer 146 may also be referred to as an organic insulating layer. For example, the planarization layer 146 may be formed of an acrylic-based organic material, but is not limited thereto.

Referring to FIGS. 4A and 4B and FIG. 5, the planarization layer 146 may be disposed on the plurality of first plate patterns 121 so as to cover an upper surface and a side surface of at least one of the buffer layer 141, the gate insulating layer 142, the first interlayer insulating layer 143, the second interlayer insulating layer 144 and the passivation layer 145. In addition, the planarization layer 146 surrounds the buffer layer 141, the gate insulating layer 142, the first interlayer insulating layer 143, the second interlayer insulating layer 144 and the passivation layer 145 together with the plurality of first plate patterns 121. Specifically, the planarization layer 146 may be disposed to cover an upper surface and a side surface of the passivation layer 145, a side surface of the first interlayer insulating layer 143, a side surface of the second interlayer insulating layer 144, a side surface of the gate insulating layer 142, a part of a side surface of the buffer layer 141 and a part of upper surfaces of the plurality of first plate patterns 121. Thus, the planarization layer 146 may compensate for steps between the side surfaces of the buffer layer 141, the gate insulating layer 142, the first interlayer insulating layer 143, the second interlayer insulating layer 144, and the passivation layer 145. And, the planarization layer 146 may enhance adhesion strength between the planarization layer 146 and the connection lines 181 and 182 disposed on side surfaces of the planarization layer 146.

Referring to FIG. 3, an incline angle of the side surface of the planarization layer 146 may be less than those of the side surfaces of the buffer layer 141, the gate insulating layer 142, the first interlayer insulating layer 143, the second interlayer insulating layer 144 and the passivation layer 145. For example, the side surface of the planarization layer 146 may have a gentle incline than the side surface of the passivation layer 145, the side surface of the first interlayer insulating layer 143, the side surface of the second interlayer insulating layer 144, the side surface of the gate insulating layer 142 and the side surface of the buffer layer 141. Thus, the connection lines 181 and 182 in contact with the side surfaces of the planarization layer 146 are disposed to have a gentle incline. Therefore, when the display device is stretched, a stress generated in the connection lines 181 and 182 may be reduced. Also, it is possible to suppress cracks in the connection lines 181 and 182 or peeling of the connection lines 181 and 182 from the side surface of the planarization layer 146.

Referring to FIG. 2 to FIGS. 4A and FIG. 4B, the connection lines 181 and 182 refer to lines that electrically connect the pads disposed on the plurality of first plate patterns 121. The connection lines 181 and 182 are disposed on the plurality of first line patterns 122. And, the connection lines 181 and 182 may also extend on the plurality of first plate patterns 121 to be electrically connected to the gate pad GP and the data pad DP on the plurality of first plate patterns 121. Also, referring to FIG. 1, the first line pattern 122 is not disposed in an area between the plurality of first plate patterns 121, in which the connection lines 181 and 182 are not disposed.

The connection lines 181 and 182 include the first connection lines 181 and the second connection lines 182. The first connection lines 181 and the second connection lines 182 are disposed between the plurality of first plate patterns 121. Specifically, the first connection lines 181 refer to lines extended in an X-axis direction X between the plurality of first plate patterns 121 among the connection lines 181 and 182. The second connection lines 182 refer to lines extended in a Y-axis direction between the plurality of first plate patterns 121 among the connection lines 181 and 182.

The connection lines 181 and 182 may be formed of a metal material such as copper (Cu), aluminum (Al), titanium (Ti) or molybdenum (Mo), or the connection lines 181 and 182 may have a laminated structure of metal materials such as copper/molybdenum-titanium (Cu/MoTi), titanium/aluminum/titanium (Ti/Al/Ti), or the like, but are not limited thereto.

In a display panel of a general display device, various lines such as a plurality of gate lines and a plurality of data lines are extended in straight lines and are disposed between a plurality of sub-pixels, and the plurality of sub-pixels are connected to a single signal line. Therefore, in the display panel of the general display device, various lines such as a gate line, a data line, a high potential voltage line and a reference voltage line are continuously extended on a substrate from one side to the other side of the display panel of an organic light emitting display device.

Unlike this, in the display device 100 according to an example embodiment of the present disclosure, various lines such as a gate line, a data line, a high potential voltage line, a reference voltage line, an initialization voltage line and the like which are formed in straight lines and considered to be used in a display panel of a general display device, are disposed only on the plurality of first plate patterns 121 and the plurality of second plate patterns 123. In the display device 100 according to an example embodiment of the present disclosure, lines formed in straight lines are disposed only on the plurality of first plate patterns 121 and the plurality of second plate patterns 123.

In the display device 100 according to an example embodiment of the present disclosure, the pads on two adjacent first plate patterns 121 may be connected by the connection lines 181 and 182. Accordingly, the connection lines 181 and 182 electrically connect the gate pads GP or the data pads DP on the two adjacent first plate patterns 121. Therefore, the display device 100 according to an example embodiment of the present disclosure may include the plurality of connection lines 181 and 182 to electrically connect various lines, such as a gate line, a data line, a high potential voltage line, a reference voltage line and the like between the plurality of first plate patterns 121. For example, gate lines may be disposed on the plurality of first plate patterns 121 disposed adjacent to each other in the first direction X. Also, the gate pads GP may be disposed on both ends of the gate lines. In this case, a plurality of gate pads GP on the plurality of first plate patterns 121 disposed adjacent to each other in the first direction X may be connected to each other by the first connection lines 181 serving as the gate lines. Therefore, the gate lines disposed on the plurality of first plate patterns 121 and the first connection lines 181 disposed on the first line patterns 122 may serve as single gate lines. The gate lines described above may be referred to as scan signal lines. Further, lines, such as an emission signal line, a low potential voltage line and a high potential voltage line which are extended in the first direction X among all of various lines that may be included in the display device 100, may also be electrically connected by the first connection lines 181 as described above.

Referring to FIG. 2 and FIGS. 4A and 4B, the first connection lines 181 may connect the gate pads GP on two first plate patterns 121 that are disposed side by side among the gate pads GP on the plurality of first plate patterns 121 disposed adjacent to each other in the first direction X. The first connection line 181 may serve as a gate line, an emission signal line, a high potential voltage line, or a low potential voltage line, but is not limited thereto. The gate pads GP on the plurality of first plate patterns 121 disposed in the first direction X may be connected by the first connection lines 181 serving as the gate lines. A single gate voltage may be transferred to the gate pads GP.

Further, referring to FIGS. 2 and 3, the second connection lines 182 may connect the data pads DP on two first plate patterns 121 that are disposed side by side among the data pads DP on the plurality of first plate patterns 121 disposed adjacent to each other in the second direction Y. The second connection line 182 may serve as a data line, a high potential voltage line, a low potential voltage line or a reference voltage line, but is not limited thereto. Internal lines on the plurality of first plate patterns 121 disposed in the second direction Y may be connected by a plurality of second connection lines 182 serving as the data lines. A single data voltage may be transferred thereto.

As shown in FIGS. 4A and 4B, the first connection line 181 may be disposed to be in contact with an upper surface and the side surface of the planarization layer 146 disposed on the first plate pattern 121. And, the first connection line 181 may be extended to an upper surface of the first line pattern 122. The second connection line 182 may be disposed to be in contact with the upper surface and the side surface of the planarization layer 146 disposed on the first plate pattern 121. And, the second connection line 182 may be extended to the upper surface of the first line pattern 122.

However, as shown in FIG. 5, there is no need for a rigid pattern to be disposed in an area where the first connection line 181 and the second connection line 182 are not disposed. Thus, the first line pattern 122, which is a rigid pattern, is not disposed under the first connection line 181 and the second connection line 182.

Meanwhile, referring to FIG. 3, a bank 147 is formed on a first connection pad CNT1, the connection lines 181 and 182 and the planarization layer 146. The bank 147 is a component to distinguish adjacent sub-pixels SPX. The bank 147 is disposed to cover at least a part of the pad PD, the connection lines 181 and 182 and the planarization layer 146. The bank 147 may be formed of an insulating material. Further, the bank 147 may contain a black material. Since the bank 147 contains a black material, the bank 147 serves to hide lines which are visible through the active area AA. The bank 147 may be formed of, for example, a transparent carbon-based mixture. Specifically, the bank 147 may contain carbon black, but is not limited thereto. The bank 147 may also be formed of a transparent insulating material. Also, although a height of the bank 147 is shown to be lower than a height of the LED 170 in FIG. 1, the height of the bank 147 is not limited thereto, and the height of the bank 147 may be equal to the height of the LED 170.

Referring to FIG. 3, the LED 170 is disposed on the first connection pad CNT1 and the second connection pad CNT2. The LED 170 includes an n-type layer 171, an active layer 172, a p-type layer 173, an n-electrode 174 and a p-electrode 175. The LED 170 of the display device 100 according to an example embodiment of the present disclosure has a flip-chip structure in which the n-electrode 174 and the p-electrode 175 are formed on one surface thereof.

The n-type layer 171 may be formed by injecting n-type impurities into gallium nitride (GaN) having excellent crystallinity. The n-type layer 171 may be disposed on a separate base substrate which is formed of a light emitting material.

The active layer 172 is disposed on the n-type layer 171. The active layer 172 is a light emitting layer that emits light in the LED 170 and may be formed of a nitride semiconductor, for example, indium gallium nitride (InGaN). The p-type layer 173 is disposed on the active layer 172. The p-type layer 173 may be formed by injecting p-type impurities into gallium nitride (GaN).

As described above, the LED 170 according to an example embodiment of the present disclosure is manufactured by sequentially laminating the n-type layer 171, the active layer 172, and the p-type layer 173, and then, etching a predetermined area of the layers to thereby form the n-electrode 174 and the p-electrode 175. In this case, the predetermined area is a space to separate the n-electrode 174 and the p-electrode 175 from each other and is etched to expose a part of the n-type layer 171. In other words, a surface of the LED 170 on which the n-electrode 174 and the p-electrode 175 are to be disposed may not be flat and may have different levels of height.

In this manner, the n-electrode 174 is disposed in the etched area, and the n-electrode 174 may be formed of a conductive material. In addition, the p-electrode 175 is disposed in a non-etched area, and the p-electrode 175 may also be formed of a conductive material. For example, the n-electrode 174 is disposed on the n-type layer 171 exposed by an etching process, and the p-electrode 175 is disposed on the p-type layer 173. The p-electrode 175 may be formed of the same material as the n-electrode 174.

An adhesive layer AD is disposed on upper surfaces of the first connection pad CNT1 and the second connection pad CNT2 and between the first connection pad CNT1 and the second connection pad CNT2. Thus, the LED 170 may be bonded onto the first connection pad CNT1 and the second connection pad CNT2. In this case, the n-electrode 174 may be disposed on the second connection pad CNT2 and the p-electrode 175 may be disposed on the first connection pad CNT1.

The adhesive layer AD may be a conductive adhesive layer formed by dispersing conductive balls in an insulating base member. Thus, when heat or pressure is applied to the adhesive layer AD, the conductive balls are electrically connected to have conductive properties in a portion of the adhesive layer AD to which heat or pressure is applied. Also, an area of the adhesive layer AD to which pressure is not applied may have insulating properties. For example, the n-electrode 174 is electrically connected to the second connection pad CNT2 through the adhesive layer AD, and the p-electrode 175 is electrically connected to the first connection pad CNT1 through the adhesive layer AD. After applying the adhesive layer AD to upper surfaces of the second connection pad CNT2 and the first connection pad CNT1 by an inkjet method or the like, the LED 170 may be transferred onto the adhesive layer AD. Then, the LED 170 may be pressed and heated to thereby electrically connect the first connection pad CNT1 to the p-electrode 175 and the second connection pad CNT2 to the n-electrode 174. However, other portions of the adhesive layer AD excluding a portion of the adhesive layer AD disposed between the n-electrode 174 and the second connection pad CNT2 and a portion of the adhesive layer AD disposed between the p-electrode 175 and the first connection pad CNT1 have insulating properties. Meanwhile, the adhesive layer AD may be separately disposed on each of the first connection pad CNT1 and the second connection pad CNT2.

Further, the first connection pad CNT1 is electrically connected to the drain electrode 164 of the driving transistor 160 and receives a driving voltage for driving the LED 170 from the driving transistor 160. Although FIG. 3 illustrates that the first connection pad CNT1 and the drain electrode 164 of the driving transistor 160 are indirectly connected to each other without directly contacting them, the present disclosure is not limited thereto, and the first connection pad CNT1 and the drain electrode 164 of the driving transistor 160 may be in direct contact. In addition, a low potential driving voltage for driving the LED 170 is applied to the second connection pad CNT2. Accordingly, when the display device 100 is turned on, different voltage levels that are applied to the first connection pad CNT1 and the second connection pad CNT2 are respectively transferred to the n-electrode 174 and the p-electrode 175, so that the LED 170 emits light.

The upper substrate 112 serves to support various components disposed under the upper substrate 112. Specifically, the upper substrate 112 may be formed by coating and hardening a material for forming the upper substrate 112 on the lower substrate 111 and the first plate patterns 121, and thus, may be disposed to be in contact with the lower substrate 111, the first plate patterns 121, the first line pattern 122 and the connection lines 181 and 182.

The upper substrate 112 may be formed of the same material as the lower substrate 111. For example, the upper substrate 112 may be formed of silicone rubber such as polydimethylsiloxane (PDMS) or elastomers such as polyurethane (PU), polytetrafluoroethylene (PTFE) and the like.

Thus, the upper substrate 112 may have flexibility. However, the materials of the upper substrate 112 are not limited thereto.

Meanwhile, although not shown in FIG. 3, a polarizing layer may also be disposed on the upper substrate 112. The polarizing layer polarizes light incident from the outside of the display device and reduces reflection of external light. Further, instead of the polarizing layer, other optical films or the like may be disposed on the upper substrate 112.

In addition, the filling layer 190 that is disposed on an entire surface of the lower substrate 111 and fills a gap between components disposed on the upper substrate 112 and the lower substrate 111 may be disposed. The filling layer 190 may be formed of a curable adhesive. Specifically, a material for forming the filling layer 190 is coated on the entire surface of the lower substrate 111 and then cured, so that the filling layer 190 may be disposed between components disposed on the upper substrate 112 and the lower substrate 111. For example, the filling layer 190 may be an optically clear adhesive (OCA), and may include an acrylic adhesive, a silicone adhesive, and a urethane adhesive.

### Circuit Structure of Active Area

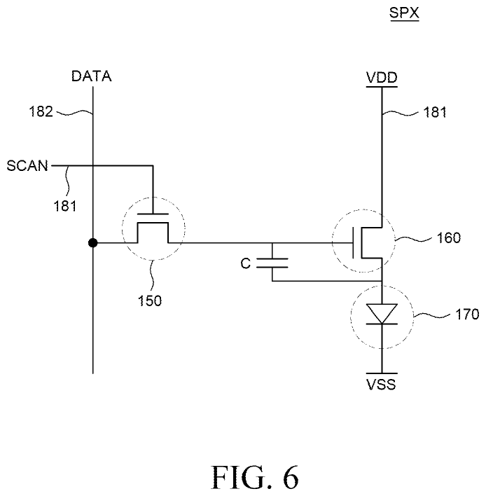

FIG. 6 is a circuit diagram of a sub-pixel of the display device according to an example embodiment of the present disclosure.

Hereinafter, for convenience of explanation, a structure and operations of the sub-pixel SPX of the display device according to an example embodiment of the present disclosure in a case in which the sub-pixel SPX is a 2T (Transistor) 1C (Capacitor) pixel circuit will be described, but the present disclosure is not limited thereto.

Referring to FIGS. 3 and 6, the sub-pixel SPX of the display device according to an example embodiment of the present disclosure may be configured to include the switching transistor 150, the driving transistor 160, a storage capacitor C, and the LED 170.

The switching transistor 150 applies a data signal DATA that is supplied through the second connection line 182 to the driving transistor 160 and the storage capacitor C according to a gate signal SCAN that is supplied through the first connection line 181.

In addition, the gate electrode 151 of the switching transistor 150 is electrically connected to the first connection line 181, the source electrode 153 of the switching transistor 150 is connected to the second connection line 182, and the drain electrode 154 of the switching transistor 150 is connected to the gate electrode 161 of the driving transistor 160.

The driving transistor 160 may operate so that a driving current according to the data voltage DATA and a high potential power VDD supplied through the first connection line 181 can flow in response to the data voltage DATA stored in the storage capacitor C.

In addition, the gate electrode 161 of the driving transistor 160 is electrically connected to the drain electrode 154 of the switching transistor 150, the source electrode of the driving transistor 160 is connected to the first connection line 181, and the drain electrode 164 of the driving transistor 160 is connected to the LED 170.

The LED 170 may operate to emit light according to the driving current that is formed by the driving transistor 160. And, as described above, the n-electrode 174 of the LED 170 may be connected to the first connection line 181 and receive a low potential power VSS, and the p-electrode 175 of the LED 170 may be connected to the drain electrode 164 of the transistor 160 and receive a driving voltage corresponding to the driving current.

The sub-pixel SPX of the display device according to an example embodiment of the present disclosure is configured to have a 2T1C structure including the switching transistor 150, the driving transistor 160, the storage capacitor C, and the LED 170, but in a case in which a compensation circuit is added, it may be configured to have various structures such as 3T1C, 4T2C, 5T2C, 6T1C, 6T2C, 7T1C, and 7T2C.

As described above, the display device according to an example embodiment of the present disclosure may include a plurality of sub-pixels on a first substrate that is a rigid substrate, and each of the plurality of sub-pixels SPX may be configured to include a switching transistor, a driving transistor, a storage capacitor, and an LED.

Accordingly, the display device according to an example embodiment of the present disclosure can be stretched by a lower substrate and also has a pixel circuit of a 2T1C structure on each first substrate, so that it can emit light depending on a data voltage in accordance with each gate timing.

### Extension Patterns

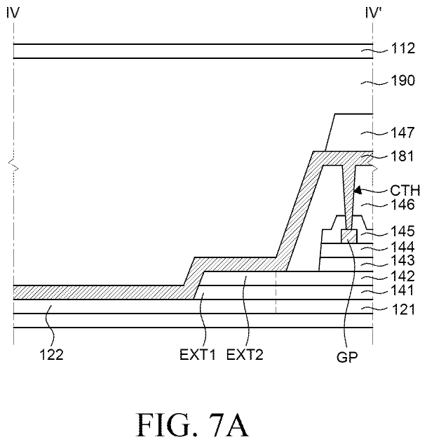

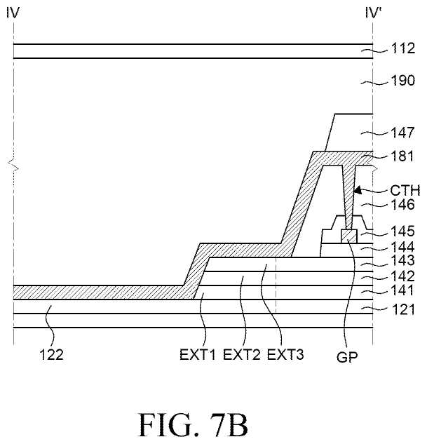

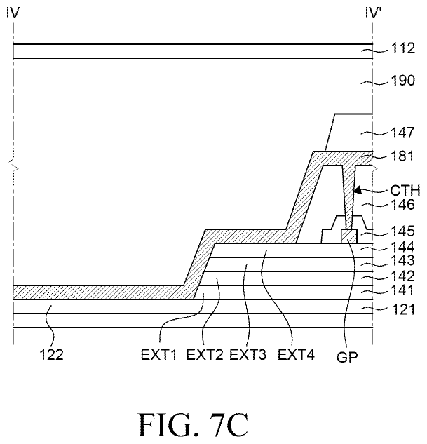

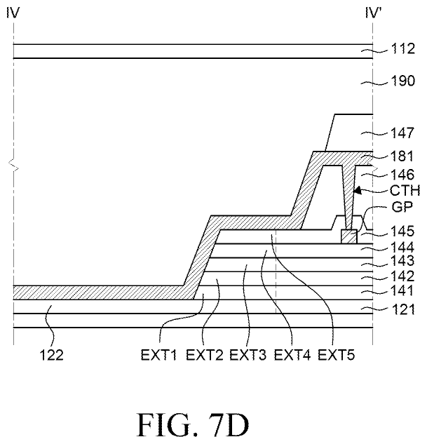

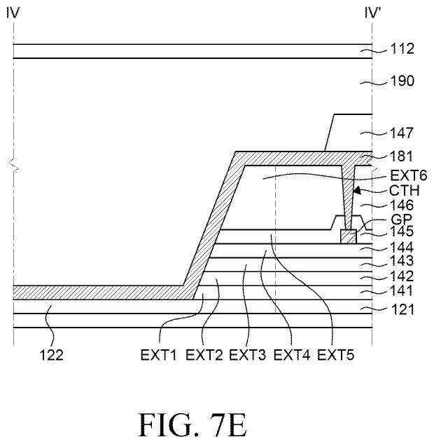

FIGS. 7A to 7E are cross-sectional views illustrating extension patterns of the display device according to an example embodiment of the present disclosure.

FIG. 2 and FIGS. 4A and 4B are referred for convenience of explanation.

Referring to FIG. 2 and FIGS. 4A and 4B, in the display device according to an example embodiment of the present disclosure, at least one of the buffer layer 141, the gate insulating layer 142, the first interlayer insulating layer 143, the second interlayer insulating layer 144, the passivation layer 145, and the planarization layer 146 that are a plurality of insulating layers may be disposed not only on the first plate pattern 121 but may also be disposed on a portion of the first line pattern 122 adjacent to the first plate pattern 121.

As illustrated in FIGS. 4A and 4B, the buffer layer 141 may extend from a top surface of the first plate pattern 121 to a top surface of a partial area of the first line pattern 122 adjacent to the first plate pattern 121. That is, a portion of the buffer layer 141 extending to a top surface of a partial area of the first line pattern 122 adjacent to the first plate pattern 121 may be defined as the extension pattern EXT. For example, a portion of the buffer layer 141 that overlaps with the first line pattern 122 is included in the extension pattern EXT.

Accordingly, as shown in FIGS. 4A and 4B, the planarization layer 146 may not cover a side surface SS of the extension pattern EXT, which is a part of the portion of the buffer layer 141. Also, the connection line 181 may be disposed on the extension pattern EXT, and the connection line 181 may extend along an upper surface US and the side surface SS of the extension pattern EXT.

Meanwhile, as shown in FIG. 4A, the thickness of the extension pattern EXT may be equal to the thickness of the buffer layer 141. However, the present disclosure is not limited thereto, and as illustrated in FIG. 4B, a thickness t2 of the extension pattern EXT may be smaller than a thickness t1 of the buffer layer 141.

For example, the thickness t1 of the buffer layer 141 may be 2 to 3 times the thickness t2 of the extension pattern EXT.

Accordingly, when the display device is stretched, shapes of the first line pattern 122 and the extension pattern EXT may be deformed. In this case, since the thickness t2 of the extension pattern EXT is relatively small in the display device according to an example embodiment of the present disclosure, the shape thereof may be more easily deformed. Accordingly, stretching stress applied to the display device according to the example embodiment of the present disclosure may be reduced.

However, the extension pattern EXT is not limited thereto and may have various stacked structures.

Specifically, as shown in FIG. 7A, the buffer layer 141 and the gate insulating layer 142 may extend from the top surface of the first plate pattern 121 to a top surface of a partial area of the first line pattern 122 adjacent to the first plate pattern 121. That is, a portion of the buffer layer 141 and a portion of the gate insulating layer 142 extending to a top surface of a partial area of the first line pattern 122 adjacent to the first plate pattern 121 may be defined as extension patterns EXT1 and EXT2. In other words, a portion of the buffer layer 141 extending to a top surface of a partial area of the first line pattern 122 adjacent to the first plate pattern 121 may be defined as a first extension pattern EXT1, and a portion of the gate insulating layer 142 extending to a top surface of a partial area of the first line pattern 122 adjacent to the first plate pattern 121 may be defined as a second extension pattern EXT2.

In some embodiments, as shown in FIG. 7B, the buffer layer 141, the gate insulating layer 142, and the first interlayer insulating layer 143 may extend from the top surface of the first plate pattern 121 to a top surface of a partial area of the first line pattern 122 adjacent to the first plate pattern 121. That is, a portion of the buffer layer 141, a portion of the gate insulating layer 142, and a portion of the first interlayer insulating layer 143 extending to a top surface of a partial area of the first line pattern 122 adjacent to the first plate pattern 121 may be defined as extension patterns EXT1, EXT2, and EXT3. In other words, a portion of the buffer layer 141 extending to a top surface of a partial area of the first line pattern 122 adjacent to the first plate pattern 121 may be defined as a first extension pattern EXT1, a portion of the gate insulating layer 142 extending to a top surface of a partial area of the first line pattern 122 adjacent to the first plate pattern 121 may be defined as a second extension pattern EXT2, and a portion of the first interlayer insulating layer 143 extending to a top surface of a partial area of the first line pattern 122 adjacent to the first plate pattern 121 may be defined as a third extension pattern EXT3.

In some embodiments, as shown in FIG. 7C, the buffer layer 141, the gate insulating layer 142, the first interlayer insulating layer 143, and the second interlayer insulating layer 144 may extend from the top surface of the first plate pattern 121 to a top surface of a partial area of the first line pattern 122 adjacent to the first plate pattern 121. That is, a portion of the buffer layer 141, a portion of the gate insulating layer 142, a portion of the first interlayer insulating layer 143, and a portion of the second interlayer insulating layer 144 extending to a top surface of a partial area of the first line pattern 122 adjacent to the first plate pattern 121 may be defined as extension patterns EXT1, EXT2, EXT3, and EXT4. In other words, a portion of the buffer layer 141 extending to a top surface of a partial area of the first line pattern 122 adjacent to the first plate pattern 121 may be defined as a first extension pattern EXT1, a portion of the gate insulating layer 142 extending to a top surface of a partial area of the first line pattern 122 adjacent to the first plate pattern 121 may be defined as a second extension pattern EXT2, a portion of the first interlayer insulating layer 143 extending to a top surface of a partial area of the first line pattern 122 adjacent to the first plate pattern 121 may be defined as a third extension pattern EXT3, and a portion of the second interlayer insulating layer 144 extending to a top surface of a partial area of the first line pattern 122 may be defined as a fourth extension pattern EXT4.

In some embodiments, as shown in FIG. 7D, the buffer layer 141, the gate insulating layer 142, the first interlayer insulating layer 143, the second interlayer insulating layer 144, and the passivation layer 145 may extend from the top surface of the first plate pattern 121 to a top surface of a partial area of the first line pattern 122 adjacent to the first plate pattern 121. That is, a portion of the buffer layer 141, a portion of the gate insulating layer 142, a portion of the first interlayer insulating layer 143, a portion of the second interlayer insulating layer 144, and a portion of the passivation layer 145 extending to a top surface of a partial area of the first line pattern 122 adjacent to the first plate pattern 121 may be defined as extension patterns EXT1, EXT2, EXT3, EXT4, EXT5, and EXT6. In other words, a portion of the buffer layer 141 extending to a top surface of a partial area of the first line pattern 122 adjacent to the first plate pattern 121 may be defined as a first extension pattern EXT1, a portion of the gate insulating layer 142 extending to a top surface of a partial area of the first line pattern 122 adjacent to the first plate pattern 121 may be defined as a second extension pattern EXT2, a portion of the first interlayer insulating layer 143 extending to a top surface of a partial area of the first line pattern 122 adjacent to the first plate pattern 121 may be defined as a third extension pattern EXT3, a portion of the second interlayer insulating layer 144 extending to a top surface of a partial area of the first line pattern 122 adjacent to the first plate pattern 121 may be defined as a fourth extension pattern EXT4, and a portion of the passivation layer 145 extending to a top surface of a partial area of the first line pattern 122 adjacent to the first plate pattern 121 may be defined as a fifth extension pattern EXT5.

In some embodiments, as shown in FIG. 7E, the buffer layer 141, the gate insulating layer 142, the first interlayer insulating layer 143, the second interlayer insulating layer 144, the passivation layer 145, and the planarization layer 146 may extend from the top surface of the first plate pattern 121 to a top surface of a partial area of the first line pattern 122 adjacent to the first plate pattern 121. That is, a portion of the buffer layer 141, a portion of the gate insulating layer 142, a portion of the first interlayer insulating layer 143, a portion of the second interlayer insulating layer 144, a portion of the passivation layer 145, and a portion of the planarization layer 146 extending to a top surface of a partial area of the first line pattern 122 adjacent to the first plate pattern 121 may be defined as extension patterns EXT1, EXT2, EXT3, EXT4, EXT5, and EXT6. In other words, a portion of the buffer layer 141 extending to a top surface of a partial area of the first line pattern 122 adjacent to the first plate pattern 121 may be defined as a first extension pattern EXT1, a portion of the gate insulating layer 142 extending to a top surface of a partial area of the first line pattern 122 adjacent to the first plate pattern 121 may be defined as a second extension pattern EXT2, a portion of the first interlayer insulating layer 143 extending to a top surface of a partial area of the first line pattern 122 adjacent to the first plate pattern 121 may be defined as a third extension pattern EXT3, a portion of the second interlayer insulating layer 144 extending to a top surface of a partial area of the first line pattern 122 adjacent to the first plate pattern 121 may be defined as a fourth extension pattern EXT4, a portion of the passivation layer 145 extending to a top surface of a partial area of the first line pattern 122 adjacent to the first plate pattern 121 may be defined as a fifth extension pattern EXT5, and a portion of the planarization layer 146 extending to a top surface of a partial area of the first line pattern 122 adjacent to the first plate pattern 121 may be defined as a sixth extension pattern EXT6.

As described above, in the display device according to an example embodiment of the present disclosure, at least one of the buffer layer 141, the gate insulating layer 142, the first interlayer insulating layer 143, the second interlayer insulating layer 144, the passivation layer 145 and the planarization layer 146 may be disposed not only on the first plate pattern 121 but may also be extended on a portion of the first line pattern 122 adjacent to the first plate pattern 121.

Accordingly, an inorganic layer or an organic layer may be disposed at a boundary between the first plate pattern 121 and the first line pattern 122. Accordingly, when etching is performed to form components on the first plate pattern 121, unnecessary over-etching may be prevented at the boundary between the first plate pattern 121 and the first line pattern 122.

Accordingly, even if the display device is repeatedly stretched, separation does not occur at the boundary between the first plate pattern 121 and the first line pattern 122. Accordingly, stretching reliability of the display device of the present disclosure may be improved.

Also, in the display device according to an example embodiment of the present disclosure, the connection line 181 may be formed on at least one extension pattern EXT. Accordingly, at the boundary between the first plate pattern 121 and the first line pattern 122, one high step of the connection line 181 may be changed to two low steps. Accordingly, since a step height of the connection line 181 may be reduced, stretching stress applied when the connection line 181 is stretched may be relatively reduced.

Accordingly, in the display device according to an example embodiment of the present disclosure, damage to the connection line due to repeated stretching may be reduced or minimized.

Hereinafter, a display device according to another example embodiment of the present disclosure will be described. Since there is a difference between the display device according to another example embodiment of the present disclosure and the display device according to an example embodiment of the present disclosure only in terms of a contact hole formed in the extension pattern, this will be described in detail.

### Another Example Embodiment of the Present Disclosure—Anchor Hole

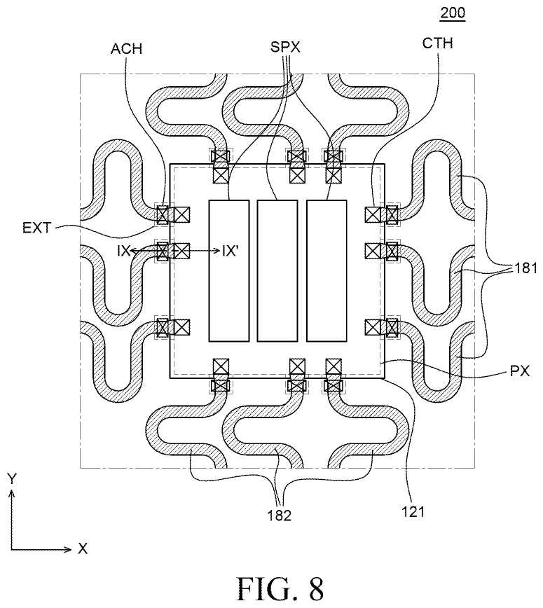

FIG. 8 is an enlarged plan view of an active area of a display device according to another example embodiment of the present disclosure.

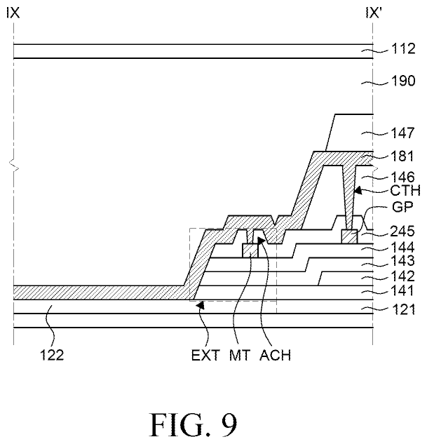

FIG. 9 is a cross-sectional view taken along cutting line IX-IX′ shown in FIG. 8.

In FIG. 9, it is illustrated that a portion of the buffer layer 141, a portion of the first interlayer insulating layer 143, a portion of the second interlayer insulating layer 144, and a portion of a passivation layer 245 extend to a top surface of a part of the first line pattern 122 adjacent to the first plate pattern 121 and configure an extension pattern EXT. However, a stacking relationship of the extension pattern EXT may be changed in various ways, as shown in FIGS. 4A and 4B and FIGS. 7A to 7E.

Referring to FIGS. 8 and 9, in a display device 200 according to another example embodiment of the present disclosure, anchor holes ACH connecting the connecting lines 181 and 182 and metal patterns MT may be disposed in the extension patterns EXT.

Specifically, the connection lines 181 and 182 overlapping the extension patterns EXT disposed on the first line pattern 122 may be disposed. In addition, the connection lines 181 and 182 disposed on the extension patterns EXT contact the metal patterns MT disposed on a layer different from that of the plurality of connection lines 181 and 182 through the anchor holes ACH.

Specifically, as shown in FIG. 9, the connection lines 181 and 182 disposed on the extension patterns EXT may contact the metal patterns MT disposed on the same layer as a source electrode and a drain electrode through the anchor holes ACH. Accordingly, the anchor hole ACH may have a shape penetrating a portion of the passivation layer 245.

Unlike this, the connection lines 181 and 182 disposed on the extension patterns EXT may contact the metal patterns MT formed on the same layer as a gate electrode through the anchor hole ACH. In the case described above, the anchor hole ACH may have a shape penetrating a portion of the first interlayer insulating layer 143 and a portion of the second interlayer insulating layer 144.

As described above, the connection lines 181 and 182 may contact the metal patterns MT through the anchor holes ACH, so that the connection lines 181 and 182 may be stably fixed.

Accordingly, in the display device 200 according to another example embodiment of the present disclosure, the connection lines 181 and 182 are brought into contact with the metal patterns MT on the extension patterns EXT, so that it is possible to prevent the connection lines from being peeled off due to repeated stretching. As a result, stretching reliability of the display device according to another example embodiment may be improved.

### Still Another Example Embodiment of the Present Disclosure—Contact Hole

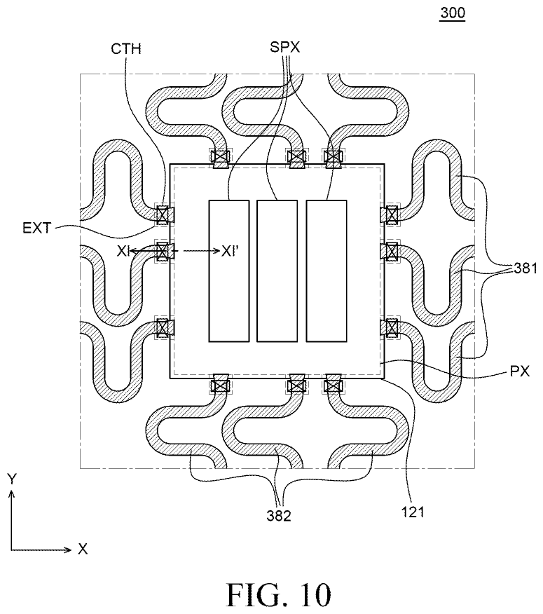

FIG. 10 is an enlarged plan view of an active area of a display device according to still another example embodiment of the present disclosure.

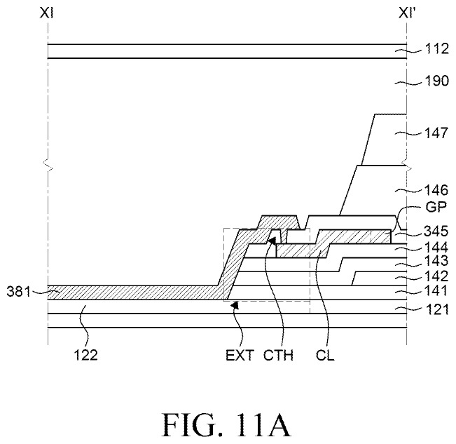

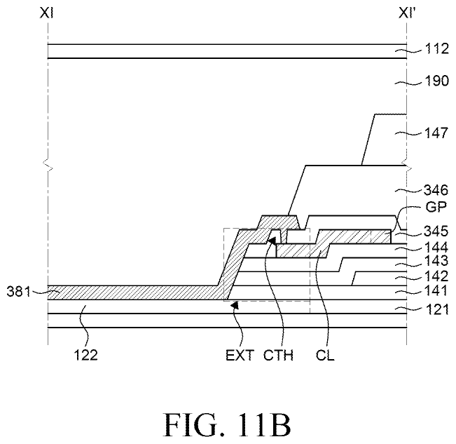

FIGS. 11A and 11B are cross-sectional views taken along cutting line XI-XI′ shown in FIG. 10.

In FIGS. 11A and 11B, it is illustrated that a portion of the buffer layer 141, a portion of the first interlayer insulating layer 143, a portion of the second interlayer insulating layer 144, and a portion of a passivation layer 345 extend to a top surface of a part of the first line pattern 122 adjacent to the first plate pattern 121 and configure an extension pattern EXT. However, a stacking relationship of the extension pattern EXT may be changed in various ways, as shown in FIGS. 4A and 4B and FIGS. 7A to 7E.

Referring to FIG. 10 and FIGS. 11A, and 11B, in a display device 300 according to still another example embodiment of the present disclosure, contact holes CTH electrically connecting connection lines 381 and 382 and a plurality of pads GP may be disposed in the extension patterns EXT.

Specifically, the connection lines 381 and 382 overlapping the extension patterns EXT disposed on the first line patterns 122 may be disposed. In addition, the connection lines 381 and 382 disposed on the extension patterns EXT contact a conductive line CL disposed on a layer different from that of the plurality of connection lines 381 and 382 through the contact holes CTH. In addition, the conductive line CL contacts the gate pad GP disposed on the same layer. Accordingly, the connection lines 381 and 382 and the plurality of pads GP may be electrically connected through the contact holes CTH disposed in the first line patterns 122.

Specifically, as shown in FIGS. 11A and 11B, the connection lines 381 and 382 disposed in the extension patterns EXT may contact the conductive line CL disposed on the same layer as a source electrode and a drain electrode through the contact holes CTH. In addition, the conductive line CL contacts the gate pad GP disposed on the same layer as a source electrode and a drain electrode. Accordingly, the connection line 381 and the gate pad GP may be electrically connected through the contact hole CTH disposed in the first line pattern 122. In the case described above, the contact hole CTH may have a shape penetrating a portion of the passivation layer 345.

As shown in FIGS. 11A and 11B, the conductive line CL extends from the gate pad GP and overlaps the extension pattern EXP. In one embodiment, the gate pad GP and the conductive line CL are continuous and contiguous to each other. Further, the gate pad GP and the conductive line CL may be formed in the same manufacturing process using the same material.

In FIG. 11A, it is illustrated that the planarization layer 146 extends only to an inside of the boundary between the first plate pattern 121 and the first line pattern 122. However, the present disclosure is not limited thereto, and as shown in FIG. 11B, the planarization layer 346 may have a shape in which it extends to an outside of the boundary between the first plate pattern 121 and the first line pattern 122 and covers a portion of the connection line 381.

Further, in one embodiment, as shown in FIG. 11A, the planarization layer 146 overlaps the gate pad GP. The planarization layer 146 also overlaps at least a portion of the conductive line CL. As shown, the planarization layer 146 does not overlap with the extension pattern EXT and does not overlap with the contact hole CTH.

According to another embodiment, as shown in FIG. 11B, the planarization layer 346 overlaps the gate pad GP and at least a portion of the conductive line CL. As shown, the planarization layer 346 further extends and contacts the connection line 381. In one embodiment, the planarization layer 346 at least partially overlaps with the contact hole CTH as shown in FIG. 11B. However, in another embodiment, the planarization layer 346 further extends and contacts the connection line 381 but does not overlap with the contact hole CTH.

Referring to FIGS. 2 and 8, in an example embodiment of the present disclosure and another example embodiment of the present disclosure, the contact holes CTH for electrical connection of connection lines are disposed in the first plate pattern 121.

Unlike, in the display device according to still another example embodiment of the present disclosure, instead of disposing the contact holes CTH for electrical connection of the connection lines 381 and 382 in the first plate pattern 121, the contact holes CTH may be disposed in the first line pattern 122.

Accordingly, by not disposing contact holes in the first plate pattern 121, a degree of freedom in designing the pixels formed in the first plate pattern 121 may be secured. As a result, the display device according to still another example embodiment can effectively secure a pixel design area formed in the first plate pattern 121.

The example embodiments of the present disclosure can also be described as follows:

A display device according to an example embodiment of the present disclosure includes a stretchable lower substrate; a pattern layer disposed on the lower substrate and including a plurality of plate patterns and a plurality of line patterns; a plurality of pixels disposed on each of the plurality of plate patterns; and a plurality of connection lines disposed on each of the plurality of line patterns to connect the plurality of pixels, wherein each of the plurality of pixels includes a plurality of insulating layers, wherein at least one of the plurality of insulating layers includes at least one extension pattern extending to the plurality of line patterns.

The plurality of connection lines may be disposed on the at least one extension pattern.

Each of the plurality of pixels may include a transistor including an active layer, a gate electrode, a source electrode and a drain electrode, a storage capacitor including an intermediate metal layer, and a light emitting element driven by the transistor, the plurality of insulating layers include, a buffer layer disposed between the plate patterns and the active layer; a gate insulating layer disposed between the active layer and the gate electrode; a first interlayer insulating layer disposed between the gate electrode and the intermediate metal layer; a second interlayer insulating layer disposed between the intermediate metal layer and the source electrode and the drain electrode; a passivation layer disposed on the source electrode and the drain electrode; and a planarization layer configured to planarize the transistor.

The at least one extension pattern may include a first extension pattern extending from the buffer layer formed on each of the plurality of plate patterns to a top surface of each of the plurality of line patterns.

The at least one extension pattern may include a second extension pattern extending from the gate insulating layer formed on each of the plurality of plate patterns to a top surface of each of the plurality of line patterns.

The at least one extension pattern may include a third extension pattern extending from the second interlayer insulating layer formed on each of the plurality of plate patterns to a top surface of each of the plurality of line patterns.

The at least one extension pattern may include a fourth extension pattern extending from the second interlayer insulating layer formed on each of the plurality of plate patterns to a top surface of each of the plurality of line patterns.

The at least one extension pattern may include a fifth extension pattern extending from the passivation layer formed on each of the plurality of plate patterns to a top surface of each of the plurality of line patterns.

The at least one extension pattern may include a sixth extension pattern extending from the planarization layer formed on each of the plurality of plate patterns to a top surface of each of the plurality of line patterns.

The plurality of connection lines may be connected to a plurality of pads through contact holes formed in the plurality of plate patterns.

The plurality of connection lines contact a plurality of metal patterns through anchor holes formed in the plurality of line patterns.

The plurality of metal patterns may be floating. In some embodiments, the plurality of metal patterns are electrically isolated. In these embodiments, the metal patterns may be referred to as dummy metal patterns as they are not electrically connected to other components of the stretchable display device. However, in other embodiments, the plurality of metal patterns may be put to use for electrical connection as needed.

The plurality of connection lines may be electrically connected to a plurality of pads through contact holes formed in the plurality of line patterns.

A display device according to another example embodiment of the present disclosure may include a stretchable substrate; a plurality of island patterns spaced apart from each other on the stretchable substrate; a plurality of pixels disposed on each of the plurality of island patterns; and a plurality of connection lines connecting the plurality of pixels, wherein each of the plurality of pixels may include a plurality of insulating layers, wherein at least one of the plurality of insulating layers overlaps the plurality of connection lines and may include at least one extension pattern extending to outsides of the plurality of island patterns.

The display device of claim may further comprise a plurality of connection patterns connecting the plurality of island patterns and overlapping the plurality of connection lines, and the at least one extension pattern may be formed on the plurality of connection patterns.

The plurality of connection lines may apply a driving signal to the plurality of pixels through contact holes formed in the plurality of island patterns.

The plurality of connection lines may be fixed to a plurality of metal patterns through anchor holes penetrating the at least one extension pattern.

The plurality of connection lines may apply a driving signal to the plurality of pixels through contact holes passing through the at least one extension pattern.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a stretchable lower substrate; and
a pattern layer disposed on the lower substrate and including a plurality of plate patterns and a plurality of line patterns;
a plurality of pixels disposed on each of the plurality of plate patterns; and
a plurality of connection lines disposed on each of the plurality of line patterns to couple the plurality of pixels,
wherein each of the plurality of pixels includes a plurality of insulating layers, and
wherein at least one of the plurality of insulating layers includes at least one extension pattern extending to the plurality of line patterns.

2. The display device of claim 1, wherein the plurality of connection lines are disposed on the at least one extension pattern.

3. The display device of claim 1, wherein each of the plurality of pixels includes a transistor including an active layer, a gate electrode, a source electrode and a drain electrode, a storage capacitor including an intermediate metal layer, and a light emitting element driven by the transistor,
wherein the plurality of insulating layers include:
a buffer layer disposed between the plate patterns and the active layer;
a gate insulating layer disposed between the active layer and the gate electrode;
a first interlayer insulating layer disposed between the gate electrode and the intermediate metal layer;
a second interlayer insulating layer disposed between the intermediate metal layer and the source electrode and the drain electrode;
a passivation layer disposed on the source electrode and the drain electrode; and
a planarization layer configured to planarize the transistor.

4. The display device of claim 3, wherein the at least one extension pattern includes a first extension pattern extending from the buffer layer formed on each of the plurality of plate patterns to a top surface of each of the plurality of line patterns.

5. The display device of claim 3, wherein the at least one extension pattern includes a second extension pattern extending from the gate insulating layer formed on each of the plurality of plate patterns to a top surface of each of the plurality of line patterns.

6. The display device of claim 3, wherein the at least one extension pattern includes a third extension pattern extending from the second interlayer insulating layer formed on each of the plurality of plate patterns to a top surface of each of the plurality of line patterns.

7. The display device of claim 3, wherein the at least one extension pattern includes a fourth extension pattern extending from the second interlayer insulating layer formed on each of the plurality of plate patterns to a top surface of each of the plurality of line patterns.

8. The display device of claim 3, wherein the at least one extension pattern includes a fifth extension pattern extending from the passivation layer formed on each of the plurality of plate patterns to a top surface of each of the plurality of line patterns.

9. The display device of claim 3, wherein the at least one extension pattern includes a sixth extension pattern extending from the planarization layer formed on each of the plurality of plate patterns to a top surface of each of the plurality of line patterns.

10. The display device of claim 1, wherein the plurality of connection lines are connected to a plurality of pads through contact holes formed in the plurality of plate patterns.

11. The display device of claim 10, wherein the plurality of connection lines contact a plurality of metal patterns through anchor holes formed in the plurality of line patterns.

12. The display device of claim 11, wherein the plurality of metal patterns are floating.

13. The display device of claim 1, wherein the plurality of connection lines are electrically connected to a plurality of pads through contact holes formed in the plurality of line patterns.

14. A display device, comprising:
a stretchable substrate; and
a plurality of island patterns spaced apart from each other on the stretchable substrate;
a plurality of pixels disposed on each of the plurality of island patterns; and
a plurality of connection lines coupling the plurality of pixels,
wherein each of the plurality of pixels includes a plurality of insulating layers, and
wherein at least one of the plurality of insulating layers overlaps the plurality of connection lines and includes at least one extension pattern extending to outsides of the plurality of island patterns.

15. The display device of claim 14, further comprising:
a plurality of connection patterns coupling the plurality of island patterns and overlapping the plurality of connection lines,
wherein the at least one extension pattern is formed on the plurality of connection patterns.

16. The display device of claim 14, wherein the plurality of connection lines apply a driving signal to the plurality of pixels through contact holes formed in the plurality of island patterns.

17. The display device of claim 16, wherein the plurality of connection lines are fixed to a plurality of metal patterns through anchor holes penetrating the at least one extension pattern.

18. The display device of claim 14, wherein the plurality of connection lines apply a driving signal to the plurality of pixels through contact holes passing through the at least one extension pattern.

19. A display device, comprising:
a substrate;
a plurality of plate patterns on the substrate, each plate pattern of the plurality of plate patterns spaced apart from each other;
a plurality of line patterns coupling adjacent plate patterns of the plurality of plate patterns;
a plurality of insulating layers on each plate pattern, the plurality of insulating layers including a first insulating layer;
an extension pattern extending from the first insulating layer and overlapping a line pattern of the plurality of line patterns;
a plurality of pixels disposed on each plate pattern; and
a plurality of connection lines coupled to the plurality of pixels, the plurality of connection lines including a first connection line,
wherein the plurality of plate patterns and the plurality of line patterns are disposed on a same layer as each other,
wherein the first connection line is disposed on the extension pattern and the first insulating layer.

20. The display device of claim 19, wherein the first insulating layer has a first thickness and the extension pattern has a second thickness different from the first thickness.

21. The display device of claim 19, wherein the extension pattern has an upper surface and a side surface extending from the upper surface, the upper surface and the side surface of the extension pattern contacting the first connection line.

22. The display device of claim 19, comprising:
a gate pad, the gad pad, in operation, transfers gate voltage to plurality of pixels, the gate pad disposed on the plurality of insulating layers; and
a contact hole extending from the first connection line to electrically connect to the gate pad.

23. The display device of claim 22, comprising:
metal pattern on the extension pattern; and
anchor hole extending from the first connection line to couple to the metal pattern.

24. The display device of claim 19, comprising:
a gate pad, the gad pad, in operation, transfers gate voltage to plurality of pixels, the gate pad disposed on the plurality of insulating layers; and
a conductive line extending from the gate pad and overlapping the extension pattern.

25. The display device of claim 24, comprising:
a contact hole overlapping the first connection line and the extension pattern,
wherein the contact hole extends from the first connection line to electrically connect to the conductive line.

26. The display device of claim 25, wherein the gate pad and the conductive line are continuous and contiguous to each other.

27. The display device of claim 25, wherein the gate pad and the conductive line are formed in a same manufacturing process.

28. The display device of claim 25, comprising a planarization layer on the first insulating layer,
wherein the planarization layer overlaps the gate pad and at least a portion of the conductive line.

29. The display device of claim 28, wherein the planarization layer at least partially overlaps with the contact hole.

30. The display device of claim 28, wherein the planarization layer does not overlap with the contact hole.
